(19) United States
(12) Patent Application Publication
(10) Pub. No.: US 2025/0294918 A1
(43) Pub. Date: Sep. 18, 2025

(54) BACK CONTACT SOLAR CELL AND PHOTOVOLTAIC MODULE

(71) Applicant: LONGI GREEN ENERGY TECHNOLOGY CO., LTD., Xi'an (CN)

(72) Inventors: Hongbo TONG, Xi'an (CN); Zhenguo LI, Xi'an (CN); Qingping LIU, Xi'an (CN); Guangbin DONG, Xi'an (CN); Chao DING, Xi'an (CN); Hongchao ZHANG, Xi'an (CN); Chen CHEN, Xi'an (CN); Xinxing XU, Xi'an (CN); Yanzeng WANG, Xi'an (CN)

(21) Appl. No.: 19/221,231

(22) Filed: May 28, 2025

Related U.S. Application Data
(63) Continuation-in-part of application No. PCT/CN2025/077013, filed on Feb. 12, 2025.

(30) Foreign Application Priority Data
Mar. 14, 2024 (CN) 202420494483.4

(51) Int. Cl. H10F 77/70; H10F 77/122; H10F 77/30

(52) U.S. Cl. CPC H10F 77/703; H10F 77/122; H10F 77/315

(57) ABSTRACT

The present disclosure discloses a solar cell and a photovoltaic module. In one example, a solar cell includes a silicon substrate; a first doped crystalline silicon region and a second doped crystalline silicon region that are arranged on a back surface of the silicon substrate; and an isolation groove, configured to isolate the first doped crystalline silicon region and the second doped crystalline silicon region. A textured structure with pyramidal structures is arranged at a bottom of the isolation groove, a distribution density of apexes of the pyramidal structures ranging from 25/100 μm² to 80/100 μm². The back surface of the silicon substrate includes an overlapping region where the first doped crystalline silicon region and the second doped crystalline silicon region overlaps, the overlapping region being a polished surface.

### CROSS-REFERENCE TO RELATED APPLICATIONS

This application is a continuation-in-part application of PCT Application No. PCT/CN2025/077013, filed on Feb. 12, 2025, which claims priority to Chinese Patent Application No. 202420494483.4, filed on Mar. 14, 2024. The disclosures of the aforementioned applications are hereby incorporated by reference in their entireties.

### TECHNICAL FIELD

The present disclosure relates to the field of photovoltaic technologies, and in particular, to a crystalline silicon solar cell and a photovoltaic module.

### BACKGROUND

A positive electrode and a negative electrode of a crystalline silicon solar cell can be located on a front surface and a back surface of the crystalline silicon solar cell respectively or can both be located on a back surface. To achieve higher efficiency, one method is to prepare a P-type or N-type region using tunneling oxide layer passivation in combination with polysilicon doping.

Currently, during preparation of the foregoing crystalline silicon solar cell, texturing is usually performed first, and then, junction region treatment is performed on a back surface, to form an interdigitated back contact (BC) structure. A doped polysilicon region in the prepared crystalline silicon solar cell is formed on a silicon substrate with a textured structure, and different doped polysilicon regions are isolated by an isolation groove.

However, that the doped polysilicon region is formed on a silicon substrate with a textured structure causes insufficient coverage of a passivation film layer in a subsequent surface passivation procedure, resulting in a failure in forming excellent surface passivation and a poor passivation effect. In addition, when a P-type or N-type doped polysilicon region and an isolation groove are formed through an existing etching process, an isolation effect and a light trapping effect of the isolation groove are poor.

### SUMMARY

The present disclosure provides a crystalline silicon solar cell and a photovoltaic module, aiming to resolve at least a technical problem of a poor passivation effect in the related art.

According to a first aspect, an embodiment of the present disclosure provides a solar cell, including:

a silicon substrate, having a front surface and a back surface opposite to the front surface;

a first doped crystalline silicon region and a second doped crystalline silicon region, both arranged on the back surface of the silicon substrate, where a first surface of the first doped crystalline silicon region away from the silicon substrate and a second surface of the second doped crystalline silicon region away from the silicon substrate are both polished surfaces; and

an isolation groove, configured to isolate the first doped crystalline silicon region and the second doped crystalline silicon region, where a first textured structure with pyramidal structures is arranged at a bottom of the isolation groove, a distribution density of apexes of the pyramidal structures ranging from 25/100 μm2 to 80/100 μm2.

The back surface of the silicon substrate includes an overlapping region corresponding to the first doped crystalline silicon region and the second doped crystalline silicon region, the overlapping region being a polished surface.

In an embodiment, along a thickness direction of the solar cell, a distance between the first surface of the first doped crystalline silicon region away from the silicon substrate and the bottom of the isolation groove ranges from 3 μm to 6 μm.

In an embodiment, along a thickness direction of the solar cell, a distance between the second surface of the second doped crystalline silicon region away from the silicon substrate and the bottom of the isolation groove ranges from 1 μm to 5 μm.

In an embodiment, a plurality of isolation grooves are provided. Along a distribution direction of the plurality of isolation grooves, a width of the isolation grooves ranges from 20 μm to 150 μm.

In an embodiment, the isolation groove extends into the silicon substrate. A depth by which the isolation groove extends into the silicon substrate ranges from 2.5 μm to 5.8 μm.

In an embodiment, a thickness of the first doped crystalline silicon region ranges from 100 nm to 500 nm. A thickness of the second doped crystalline silicon region ranges from 100 nm to 500 nm.

In an embodiment, a cross-sectional shape of the isolation groove is rectangular or trapezoidal.

In an embodiment, a tunneling oxide layer is further included. The tunneling oxide layer is located between the silicon substrate and the first doped crystalline silicon region, and is located between the silicon substrate and the second doped crystalline silicon region. A thickness of the tunneling oxide layer ranges from 0.5 nm to 3 nm.

In an embodiment, a second textured structure with pyramidal structures is arranged on the front surface of the silicon substrate.

According to a second aspect, an embodiment of the present disclosure provides a photovoltaic module, including the solar cell according to any one of the foregoing.

In an embodiment of the present disclosure, the first surface and the second surface are both polished surfaces. To be specific, the first surface and the second surface are both non-textured structures. The first surface and the second surface have high flatness and low surface roughness, which is conducive to passivation. A passivation effect of a polished surface is significantly better than a passivation effect of a textured surface, which enhances surface passivation performance of a finally formed crystalline silicon solar cell. In addition, the polished surfaces can provide better protection and barrier effects during alkaline etching, thereby enhancing etching barrier performance, so that structures of the formed first doped crystalline silicon region and the formed second doped crystalline silicon region are denser. In addition, after the passivation effect is improved, a specific voltage gain can be obtained, thereby improving efficiency of the solar cell.

In addition, in a same wet etching process, when a distribution density of apexes of the pyramidal structures ranges from 25/100 μm2 to 80/100 μm2, a depth of the finally formed isolation groove is large, which implements effective isolation between the first doped crystalline silicon region and the second doped crystalline silicon region. In addition, when the distribution density of the apexes of the pyramidal structures at the bottom of the isolation groove ranges from 25/100 μm2 to 80/100 μm2, a good light trapping effect is achieved, which is conducive to improving efficiency of the solar cell. The foregoing description is only an overview of technical solutions of the present disclosure. To understand the technical means of the present disclosure more clearly, implementation can be performed based on content of the specification. In addition, to make the foregoing and other objectives, features, and advantages of the present disclosure more comprehensible, specific embodiments of the present disclosure are specifically listed below.

### BRIEF DESCRIPTION OF THE DRAWINGS

FIG. 1 is a schematic structural diagram of a back contact solar cell according to an embodiment of the present disclosure;

FIG. 2 is a schematic structural diagram of an intermediate member 1 in a process of preparing a back contact solar cell;

FIG. 3 is a schematic structural diagram of an intermediate member 2 in a process of preparing a back contact solar cell;

FIG. 4 is a schematic structural diagram of an intermediate member 3 in a process of preparing a back contact solar cell;

FIG. 5 is a schematic structural diagram of an intermediate member 4 in a process of preparing a back contact solar cell; and

FIG. 6 is a schematic structural diagram of an intermediate member 5 in a process of preparing a back contact solar cell.

### REFERENCE SIGNS

10—silicon substrate,

11—back surface,

111—overlapping region,

12—front surface,

121—second textured structure,

20—tunneling oxide layer,

30—first doped crystalline silicon region,

31—first surface,

40—second doped crystalline silicon region,

41—second surface,

50—isolation groove,

51—first textured structure,

60—polysilicon layer,

70—boron-doped polysilicon,

80—phosphorus-doped polysilicon, and

90—laser.

### DETAILED DESCRIPTION

The following describes exemplary embodiments of the present disclosure in further detail with reference to the accompanying drawings. Although exemplary embodiments of the present disclosure are shown in the accompanying drawings, it should be understood that, the present disclosure can be implemented in various manners and should not be limited by the embodiments described herein. On the contrary, embodiments are provided, so that the present disclosure can be understood more thoroughly and a scope of the present disclosure can be completely conveyed to a person skilled in the art.

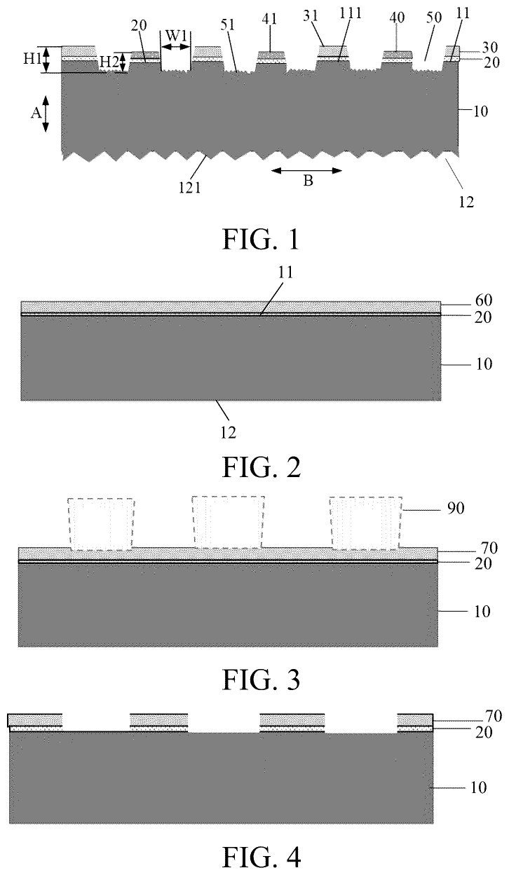

According to a first aspect, referring to FIG. 1, an embodiment of the present disclosure discloses a back contact solar cell, including:

a silicon substrate 10, having a front surface 12 and a back surface 11 opposite to the front surface 12;

a first doped crystalline silicon region 30 and a second doped crystalline silicon region 40, both arranged on the back surface 11 of the silicon substrate 10, where a first surface 31 of the first doped crystalline silicon region 30 away from the silicon substrate 10 and a second surface 41 of the second doped crystalline silicon region 40 away from the silicon substrate 10 being both polished surfaces; and

an isolation groove 50, configured to isolate the first doped crystalline silicon region 30 and the second doped crystalline silicon region 40, where a first textured structure 51 with pyramidal structures is arranged at a bottom of the isolation groove 50, a distribution density of apexes of the pyramidal structures ranging from 25/100 μm2 to 80/100 μm2.

The back surface 11 of the silicon substrate 10 includes an overlapping region 111 corresponding to the first doped crystalline silicon region 30 and the second doped crystalline silicon region 40. The overlapping region 111 is a polished surface.

It should be noted that that the foregoing distribution density of the apexes of the pyramidal structures is 25/100 μm2 means that 25 apexes are distributed on every 100 μm2 of the bottom of the isolation groove. That the foregoing distribution density of the apexes of the pyramidal structures is 80/100 μm2 means that 80 apexes are distributed on every 100 μm2 of the bottom of the isolation groove.

Specifically, the silicon substrate 10 is an N-type monocrystalline silicon wafer or a P-type monocrystalline silicon wafer. The back surface 11 of the silicon substrate 10 is a back surface, and the front surface 12 of the silicon substrate 10 is a light receiving surface. The first doped crystalline silicon region 30 and the second doped crystalline silicon region 40 both include polysilicon. The first doped crystalline silicon region 30 is a P-type doped crystalline silicon region. The P-type doped crystalline silicon region includes boron. A concentration of the boron ranges from 3×10¹⁸/cm³ to 3×10²⁰/cm³. The second doped crystalline silicon region 40 is an N-type doped crystalline silicon region. The N-type doped crystalline silicon region includes phosphorus. A concentration of the phosphorus ranges from 2×10²⁰/cm³ to 2×10²¹/cm³.

During preparation of the back contact solar cell, a tunneling oxide layer 20 and a polysilicon layer 60 can be first deposited on the back surface 11 of the silicon substrate 10, and then the polysilicon layer 60 is doped with boron, to form boron-doped polysilicon 70. After procedures such as laser processing and chemical etching, the first doped crystalline silicon region 30 is finally formed. The polysilicon layer 60 can be deposited through a process such as chemical vapor deposition (CVD) or low-pressure chemical vapor deposition (LPCVD). Before deposition of the polysilicon layer 60 on the back surface of the silicon substrate 10, alkaline polishing is first performed on the silicon substrate 10, to smoothen and clean the surface of the silicon substrate 10. In this way, the back surface 11 of the silicon substrate 10 is already a polished surface before the deposition of the polysilicon layer 60, so that the overlapping region 111 in the back surface 11 is a polished surface. The overlapping region 111 is specifically a region that is in contact with the tunneling oxide layer 20 and that is in the back surface 11 in FIG. 1. During the alkaline polishing, an alkaline solution with an alkaline concentration of 10% to 40% can be used.

The first surface 31 and the second surface 41 are both polished surfaces. To be specific, the first surface 31 and the second surface 41 are both non-textured structures. The first surface 31 and the second surface 41 have high flatness and low surface roughness, which is conducive to passivation. A passivation effect of a polished surface is significantly better than a passivation effect of a textured surface, which enhances surface passivation performance of a PN junction region in a finally formed back contact solar cell. In addition, the polished surfaces can provide better protection and barrier effects during alkaline etching, thereby enhancing etching barrier performance, so structures of the formed first doped crystalline silicon region 30 and the formed second doped crystalline silicon region 40 are denser. In addition, after the passivation effect is improved, a specific voltage gain can be obtained, thereby improving efficiency of the back contact solar cell.

The isolation groove 50 is located between the first doped crystalline silicon region 30 and the second doped crystalline silicon region 40, and is configured to isolate the first doped crystalline silicon region 30 and the second doped crystalline silicon region 40. The distribution density of the apexes of the pyramidal structures ranging from 25/100 μm2 to 80/100 μm2 is specifically 25/100 μm2, 30/100 μm2, 40/100 μm2, 50/100 μm2, 70/100 μm2, 80/100 μm2, or the like. In an embodiment of the present disclosure, in a same wet etching process, when a distribution density of apexes of pyramidal structures in the first textured structure 51 is large, a depth of the finally formed isolation groove 50 is large, which implements effective isolation between the first doped crystalline silicon region 30 and the second doped crystalline silicon region 40, thereby reducing a short-circuit leakage risk of the PN junction region. In addition, when the distribution density of apexes of the pyramidal structures at the bottom of the isolation groove ranges from 25/100 μm2 to 80/100 μm2, a good light trapping effect is achieved, which is conducive to improving efficiency of the solar cell.

A wet etching process is used to form the isolation groove 50. An etching solution used in the wet etching process includes alkali and an auxiliary additive. A concentration of the alkali ranges from 2% to 15%, and the alkali is specifically potassium hydroxide, sodium hydroxide, or the like. A volume ratio of the auxiliary additive ranges from 0.5% to 4%, and components of the auxiliary additive include sodium benzoate, a defoaming agent, a surfactant, and the like. The auxiliary additive functions to protect a region not scanned by laser.

Along a thickness direction of the back contact solar cell, a distance between the first surface 31 of the first doped crystalline silicon region 30 away from the silicon substrate 10 and the bottom of the isolation groove 50 ranges from 3 μm to 6 μm.

Specifically, for the thickness direction of the back contact solar cell, reference can be made to a direction shown by an arrow in FIG. 1. For the distance between the first surface 31 and the bottom of the isolation groove 50, reference can be made to H1 shown in FIG. 1. The distance H1 between the first surface 31 and the bottom of the isolation groove 50 ranges from 3 μm to 6 μm, and is specifically 3 μm, 3.5 μm, 4 μm, 4.5 μm, 5 μm, 5.5 μm, 6 μm, or the like. When the distance between the first surface 31 of the first doped crystalline silicon region 30 and the bottom of the isolation groove 50 falls within the foregoing range, a depth of the isolation groove 50 can be ensured, thereby better isolating the first doped crystalline silicon region 30 and the second doped crystalline silicon region 40.

Along a thickness direction of the back contact solar cell, a distance between the second surface 41 of the second doped crystalline silicon region 40 away from the silicon substrate 10 and the bottom of the isolation groove 50 ranges from 1 μm to 5 μm.

Specifically, for the distance between the second surface 41 and the bottom of the isolation groove 50, reference can be made to H2 shown in FIG. 1. The distance H2 between the second surface 41 and the bottom of the isolation groove 50 ranges from 1 μm to 5 μm, and is specifically 1 μm, 1.5 μm, 2 μm, 2.5 μm, 3 μm, 3.5 μm, 4 μm, 4.5 μm, 5 μm, or the like. When the distance between the second surface 41 of the second doped crystalline silicon region 40 and the bottom of the isolation groove 50 falls within the foregoing range, a depth of the isolation groove 50 can be ensured, thereby better isolating the first doped crystalline silicon region 30 and the second doped crystalline silicon region 40.

A plurality of isolation grooves 50 are provided. Along a distribution direction of the plurality of isolation grooves 50, a width of the isolation grooves 50 ranges from 20 μm to 150 μm.

Specifically, for an arrangement direction of the plurality of isolation grooves 50, reference can be made to a direction shown by an arrow B in FIG. 1. For a width of the isolation grooves 50, reference can be made to W1 shown in FIG. 1. The width W1 of the isolation grooves 50 is specifically a width of bottoms of the isolation grooves 50. The width

W1 of the isolation grooves 50 ranges from 20 μm to 150 μm, and is specifically 20 μm, 25 μm, 30 μm, 39 μm, 45 μm, 50 μm, 55 μm, 60 μm, 63 μm, 70 μm, 80 μm, 90 μm, 100 μm, 110μm, 120 μm, 130 μm, 140 μm, 150 μm, or the like. When the width of the isolation grooves 50 falls within the foregoing range, effective isolation between the first doped crystalline silicon region 30 and the second doped crystalline silicon region 40 can be ensured.

The isolation groove 50 extends into the silicon substrate 10. In addition, a depth by which the isolation groove 50 extends into the silicon substrate 10 ranges from 2.5 μm to 5.8 μm.

Specifically, the depth by which the isolation groove 50 extends into the silicon substrate 10 is specifically a distance between the bottom of the isolation groove 50 and the back surface 11 of the silicon substrate 10 along the thickness direction of the back contact solar cell. A depth by which the isolation groove 50 extends into the silicon substrate 10 ranges from 2.5 μm to 5.8 μm, and is specifically 2.5 μm, 3 μm, 3.5 μm, 4 μm, 4.5 μm, 5 μm, 5.8 μm, or the like. When the depth by which the isolation groove 50 extends into the silicon substrate 10 falls within the foregoing range, the depth of the isolation groove 50 can be ensured, thereby better isolating the first doped crystalline silicon region 30 and the second doped crystalline silicon region 40.

A thickness of the first doped crystalline silicon region 30 ranges from 100 nm to 500 nm. A thickness of the second doped crystalline silicon region 40 ranges from 100 nm to 500 nm. The thickness of the second doped crystalline silicon region 40 is equal to or not equal to the thickness of the first doped crystalline silicon region 30.

A cross-sectional shape of the isolation groove 50 is rectangular or trapezoidal. A cross-sectional shape of the isolation groove 50 is trapezoidal in an embodiment. A cross section of the isolation groove 50 specifically refers to a cross section perpendicular to an extension direction of the isolation groove 50. When the cross-sectional shape of the isolation groove 50 is rectangular or trapezoidal, the shape is simple, leading to easy preparation.

The back contact solar cell provided in an embodiment of the present disclosure further includes a tunneling oxide layer 20. The tunneling oxide layer 20 is located between the silicon substrate 10 and the first doped crystalline silicon region 30, and is located between the silicon substrate 10 and the second doped crystalline silicon region 40. A thickness of the tunneling oxide layer 20 ranges from 0.5 nm to 3 nm.

Specifically, during preparation of the back contact solar cell, the tunneling oxide layer 20 is first deposited on the back surface 11 of the silicon substrate 10, and a polycrystalline silicon layer 60 is then deposited. A thickness of the tunneling oxide layer 20 is specifically 0.5 nm, 1 nm, 1.2 nm, 1.8 nm, 2.5 nm, 3 nm, or the like.

A second textured structure 121 with pyramidal structures is arranged on the front surface 12 of the silicon substrate 10.

Specifically, during preparation, acid etching is first performed on the front surface 12 of the silicon substrate 10, to remove an oxide layer on the front surface 12. After the oxide layer is removed, the second textured structure 121 is formed by using a wet etching process. Arrangement of the second textured structure 121 can reduce reflectivity of the front surface 12 of the silicon substrate 10.

A specific process of preparing a back contact solar cell according to an embodiment of the present disclosure is, for example:

S1: Provide a silicon substrate 10. The silicon substrate 10 is an N-type monocrystalline silicon wafer or a P-type monocrystalline silicon wafer.

S2: Polish the silicon substrate 10. Specifically, the silicon substrate 10 is polished by using an alkaline solution having an alkaline concentration of 10% to 40%, to smoothen and clean the surface of the silicon substrate 10.

S3: Deposit a tunneling oxide layer 20 and a polysilicon layer 60 on the polished silicon substrate 10. For a structure after the deposition, reference can be made to an intermediate member 1 shown in FIG. 2. A thickness of the deposited tunneling oxide layer 20 ranges from 0.5 nm to 3 nm, and a thickness of the deposited polysilicon layer 60 ranges from 100 nm to 500 nm.

S4: Dope the deposited polysilicon layer 60. A doped element is not limited to an accepter impurity and a donor impurity such as boron and phosphorus, and a doping concentration of the boron ranges from 3×10¹⁸ /cm³ to 3×10²⁰/cm³, and a doping concentration of the phosphorus ranges from 2×2×10²⁰/cm³ to 2×10²¹/cm³. In this step, boron is doped in an embodiment, and boron-doped polysilicon 70 is formed after boron is doped.

S5: Perform laser film opening. The laser film opening is patterning a surface of a specific silicon wafer by using laser energy. For a position scanned by laser 90, reference can be made to a position shown in FIG. 3. The laser 90 is obtained through a laser. The laser is a nanosecond, picosecond, or femtosecond laser. A power of the laser ranges from 10 W to 60 W, and a diameter of a laser spot ranges from 50 μm to 300 μm.

S6: Perform wet etching. A position scanned by the laser 90 is etched, and a position not scanned by the laser 90 is not etched. An etching solution used in this step includes alkali and an auxiliary additive. A concentration of the alkali ranges from 4% to 20%, and the alkali is specifically potassium hydroxide, sodium hydroxide, or the like. A volume ratio of the auxiliary additive ranges from 0.5% to 5%, and components of the auxiliary additive include sodium benzoate, a defoaming agent, a surfactant, and the like. The auxiliary additive functions to protect a region not scanned by laser, to ensure polishing of the surface. A process of the wet etching is performed in stages in different chemical solution tanks having different chemical formulas and different cleaning functions. During the wet etching, a temperature ranges from 65° C. to 85° C., a process time ranges from 50 s to 300 s, and an etching depth ranges from 0.5 μm to 3 μm. For a structure obtained after the wet etching, reference can be made to an intermediate member 3 shown in FIG. 4. A groove is formed in the intermediate member 3.

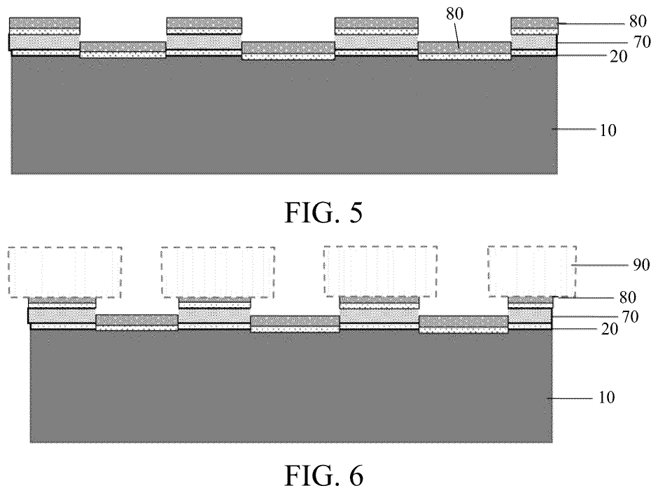

S7: Prepare another, different type of doped polysilicon. When boron is doped in S4, phosphorus-doped polysilicon is prepared in this step. During preparation of the phosphorus-doped polysilicon, a tunneling oxide layer and a polysilicon layer are deposited again, and the polysilicon layer is then doped with phosphorus, so that phosphorus-doped polysilicon 80 is prepared. A doping concentration of the phosphorus ranges from 2×10²⁰/cm³ to 2×10²¹/cm³. For a structure obtained after preparation of the another, different type of doped polysilicon region is completed, reference can be made to an intermediate member 4 shown in FIG. 5.

S8: Perform acid etching on a front surface 12 of the silicon substrate 10, to remove an oxide layer on the front surface 12.

S9: Perform laser film opening again. For a position scanned by the laser 90, reference can be made to a position shown in FIG. 6. The laser 90 is obtained through a laser. The laser is a nanosecond, picosecond, or femtosecond laser. A power of the laser ranges from 10 W to 100 W, and a diameter of a laser spot ranges from 50 μm to 350 μm.

S10: Perform wet etching on the front surface and a back surface, to form a textured surface on the front surface, form a polished surface in a doped polysilicon region of the back surface, and form a first textured structure with pyramidal structures at a bottom of an isolation groove on the back surface. A distribution density of apexes of the pyramidal structures ranges from 25/100 μm2 to 80/100 μm2. A position scanned by the laser 90 is etched, and a position not scanned by the laser 90 is not etched. An etching solution used for texturing and wet etching in this step includes alkali and an auxiliary additive. A concentration of the alkali ranges from 2% to 15%, and the alkali is specifically potassium hydroxide, sodium hydroxide, or the like. A volume ratio of the auxiliary additive ranges from 0.5% to 4%, and components of the auxiliary additive include sodium benzoate, a defoaming agent, a surfactant, and the like. The auxiliary additive functions to protect a region not scanned by laser, to ensure polishing of the polysilicon surface. A process of the wet etching is performed in stages in different chemical solution tanks having different chemical formulas and different cleaning functions. During the wet etching, a temperature ranges from 55° C. to 85° C., a process time ranges from 40 s to 400 s, and an etching depth ranges from 1 μm to 5 μm, to ensure a depth of the finally formed isolation groove 50 and a distribution density of apexes of the pyramidal structures at the bottom of the isolation groove 50. For a structure obtained after the wet etching in S10, reference can be made to a structure shown in FIG. 1.

S11: Perform subsequent surface passivation and metallization procedures, to prepare a back contact solar cell.

In some implementations, the present disclosure further includes a front-surface passivation anti-reflection layer (e.g., a first passivation anti-reflection layer) located on the front surface of the silicon substrate 10 and a back-surface passivation anti-reflection layer (e.g., a second passivation anti-reflection layer) located on the back surface of the silicon substrate 10. A passivation anti-reflection layer herein can produce a passivation effect and/or can produce an anti-reflection effect. A material of the passivation anti-reflection layer can be selected from silicon oxide, silicon oxynitride, and/or the like. There is no limitation on a specific material of the passivation anti-reflection layer. The passivation anti-reflection layer can be prepared through any suitable method, such as plasma enhanced chemical vapor deposition (PECVD). A specific preparation method for the passivation anti-reflection layer is not specifically limited.

The front surface of the silicon substrate 10 has a second textured structure with pyramidal structures, and a bottom region of an isolation groove on the back surface of the silicon substrate 10 has a first textured structure with pyramidal structures. An apex angle of the pyramidal structures of the first textured structure is greater than an apex angle of the pyramidal structures of the second textured structure. The apex angle of the pyramidal structures of the second textured structure is an apex angle of a cross-section of the pyramidal structures of the second textured structure, and can be measured through a scanning electron microscope (SEM). The apex angle of the pyramidal structures of the first textured structure is an apex angle of a cross-section of the pyramidal structures of the first textured structure, and can be measured through a scanning electron microscope (SEM). In some implementations, the apex angle of the pyramidal structures of the second textured structure is smaller than the apex angle of the pyramidal structures of the first textured structure, that is, the pyramidal structures of the second textured structure can be more acute, have a sharper tip, and/or have a steeper slope, compared to the pyramidal structures of the first textured structure. As such, in some implementations, the second textured structure can have a larger specific surface area than the second textured structure, that is, the front surface of the silicon substrate 10 can have a lower reflectivity and a better light trapping effect, which can increase a short-circuit current and ultimately improve photoelectric conversion efficiency of the solar cell. In some implementations, a need for passivation on the front surface of the solar cell is smaller than a need for passivation on the back surface of the solar cell. Therefore, the apex angle of the pyramidal structures of the first textured structure on the back surface of the silicon substrate 10 can be larger, that is, the first textured structure on the back surface of the silicon substrate 10 can be smoother, which can be conducive to preparing a thicker back-surface passivation anti-reflection layer, thereby achieving a good passivation effect. Since the apex angle of the pyramidal structures of the first textured structure at the bottom of the isolation groove on the back surface is large, which may not be conducive to light trapping, and the first textured structure can be formed only at the bottom of the isolation groove on the back surface, bifaciality of the solar cell may not be insufficient. Bifaciality of a solar cell can refer to the capability and efficiency of the solar cell to generate electrical power from light absorbed on both its front surface and back surface. In some implementations, to improve bifaciality of the solar cell, the distribution density of the apexes of the pyramidal structures of the first textured structure can be set to 25/100 μm2 to 80/100 μm2, to optimize the distribution density of the pyramidal structures, which may effectively alleviate the problem of insufficient light trapping caused by the large apex angle of the pyramidal structures of the first textured structure at the bottom of the isolation groove, thereby improving the bifaciality of the solar cell while taking the passivation effect on the back surface into account.

It should be noted that, an apex angle of the pyramidal structures of the first textured structure is greater than an apex angle of the pyramidal structures of the second textured structure, and a specific difference between the two apex angles is not specifically limited. In the present disclosure, that an apex angle of the pyramidal structures of the first textured structure is greater than an apex angle of the pyramidal structures of the second textured structure can be understood as that each apex angle in all apex angles of the pyramidal structures of the first textured structure is greater than each apex angle in all apex angles of the pyramidal structures of the second textured structure. Alternatively, that an apex angle of the pyramidal structures of the first textured structure is greater than an apex angle of the pyramidal structures of the second textured structure can be understood as that each apex angle in a first preset proportion of a total quantity of all apex angles of the pyramidal structures of the first textured structure is greater than each apex angle in a second preset portion of a total quantity of all apex angles of the pyramidal structures of the second textured structure. An entire region of the front surface of the silicon substrate 10 has a second textured structure, or only a partial region of the front surface of the silicon substrate 10 has a second textured structure, which is not specifically limited.

In some implementations, the apex angle of the pyramidal structures of the second textured structure is less than 79°, the apex angle of the pyramidal structures of the second textured structure is smaller, and the pyramidal structures of the second textured structure are sharper, so that the second textured structure has a larger specific surface area, that is, the front surface of the silicon substrate 10 has lower reflectivity and a better light trapping effect, which can increase a short-circuit current and ultimately improve photoelectric conversion efficiency of the solar cell. In addition, the front-surface passivation anti-reflection layer prepared on the second textured structure can have a proper thickness, which can meet a need for passivation on the front surface of the silicon substrate 10 and avoid material waste.

That the apex angle of the pyramidal structures of the second textured structure is less than 79° can be that each apex angle in all apex angles of the pyramidal structures of the second textured structure is less than 79°, or can be that each apex angle in a third preset proportion of a total quantity of all apex angles of the pyramidal structures of the second textured structure is less than 79°.

The apex angle of the pyramidal structures of the first textured structure at the bottom of the isolation groove on the back surface of the silicon substrate 10 is larger, that is, the first textured structure on the back surface of the silicon substrate 10 is smoother, which can be conducive to preparing a thicker back-surface passivation anti-reflection layer, thereby achieving a good passivation effect.

That the apex angle of the pyramidal structures of the first textured structure is greater than or equal to 79° can be that each apex angle in all apex angles of the pyramidal structures of the first textured structure is greater than or equal to 79°, or can be that each apex angle in a fourth preset proportion of a total quantity of all apex angles of the pyramidal structures of the first textured structure is greater than or equal to 79°.

In some implementations, the front-surface passivation anti-reflection layer includes a first portion located on the second textured structure, and the back-surface passivation anti-reflection layer includes a second portion located on the first textured structure. A thickness of the first portion is less than a thickness of the second portion. A light receiving surface of the solar cell may have a greater need for anti-reflection and a smaller need for passivation. The pyramidal structures of the second textured structure can be sharper. Therefore, the thickness of the first portion of the front-surface passivation anti-reflection layer located on the second textured structure can be smaller, and the light receiving surface of the solar cell can have better anti-reflection performance and weaker passivation performance, which can satisfy the needs of the light receiving surface of the solar cell for anti-reflection and passivation, and can increase a short-circuit current and ultimately improve photoelectric conversion efficiency of the solar cell. In addition, an appearance of the solar cell can be uniformly black, which is more beautiful and can avoid waste. The back surface of the solar cell may have a smaller need for anti-reflection and a greater need for passivation. The first textured structure can be smoother. Therefore, the thickness of the second portion of the back-surface passivation anti-reflection layer located on the first textured structure can be larger, and the back surface of the solar cell can have better passivation performance and weaker anti-reflection performance, which can satisfy the needs of the back surface of the solar cell for anti-reflection and passivation, and can increase a short-circuit current and ultimately improve photoelectric conversion efficiency of the solar cell. In addition, in the present disclosure, after light enters passivation anti-reflection layers with different thicknesses, an optical path of the light can change a larger quantity of times, which can increase an optical distance, and when combined with the textured structures of the present disclosure, can further increase absorption of the light, achieve a better light trapping effect, further increase the short-circuit current, and further improve the photoelectric conversion efficiency of the solar cell.

In some implementations, the back-surface passivation anti-reflection layer includes: a second portion located on the first textured structure and a third portion located on the polished surface. A thickness of the second portion can be less than a thickness of the third portion. Specifically, the polished surface can be smoother than the first textured structure, so that it is easy to prepare a thicker back-surface passivation anti-reflection layer 3. In addition, in the present disclosure, after light enters passivation anti-reflection layers with different thicknesses, an optical path of the light can change a larger quantity of times, which can increase an optical distance, and when combined with the textured structures of the present disclosure, can further increase absorption of the light, achieve a better light trapping effect, and further increase the short-circuit current.

In some implementations, the thickness of the first portion, the thickness of the second portion, and the thickness of the third portion satisfy a relationship that the thickness of the third portion is the largest, the thickness of the second portion is the second largest or between the thickness of the first portion and the thickness of the second portion, and the thickness of the first portion is the smallest, which can achieve an optimal passivation effect at all the positions. In addition, in the present disclosure, the thickness of the passivation anti-reflection layer can be set based on a need for passivation, which can reduce material waste.

According to a second aspect of the present disclosure, the solar cell of the present disclosure can also be a double-sided solar cell. For example, the double-sided solar cell can be a TOPCon solar cell, where a P-type region and an N-type region are formed on a front surface and a back surface of the solar cell, respectively. According to some implementations of a double-sided solar cell, an N-type crystalline silicon substrate 10 is used, a front surface of the N-type crystalline silicon substrate 10 is doped with boron, to form a P-type emitter, and a tunneling oxide layer and N-type doped polysilicon on the tunneling oxide layer are formed on a back surface of the double-sided solar cell. In some implementations, on the back surface of the solar cell, the first doped crystalline silicon region and the second doped crystalline silicon region according to the first aspect of the present disclosure are both formed as N-type doped polycrystalline silicon regions, and an isolation groove is provided between adjacent N-type doped polycrystalline silicon regions. A specific form of the isolation groove between the adjacent N-type doped polycrystalline silicon regions can be the same as that according to the first aspect of the present disclosure. Further, the front surface of the double-sided solar cell can have the second textured structure according to the first aspect of the present disclosure, and the back surface of the double-sided solar cell can have the first textured structure and the polished structure according to the first aspect of the present disclosure, which is not described herein again. Effects that the double-sided solar cell according to the present disclosure can achieve are the same as those of the solar cell according to the first aspect of the present disclosure.

According to a third aspect, the present disclosure further provides a photovoltaic module, including the crystalline silicon solar cell according to any one of the foregoing. Because the photovoltaic module includes the foregoing crystalline silicon solar cell, the photovoltaic module also has beneficial effects of the foregoing crystalline silicon solar cell. Details are not described herein again.

It should be noted that terms “include”, “comprise”, and any variants thereof are intended to cover a non-exclusive inclusion. Therefore, in the context of a process, method, object, or apparatus that includes a series of elements, the process, method, object, or apparatus not only includes such elements, but also includes other elements not specified expressly, or may include inherent elements of the process, method, object, or device. Without more limitations, elements defined by a sentence “including one” does not exclude that there are still other same elements in the process, method, object, or apparatus.

Although embodiments of the present disclosure have been described above with reference to the accompanying drawings, the present disclosure is not limited to the specific implementations described above, and the specific implementations described above are merely exemplary and not limitative. A person of ordinary skill in the art may make various variations under the teaching of the present disclosure without departing from the spirit of the present disclosure and the protection scope of the claims, and such variations shall all fall within the protection scope of the present disclosure.

What is claimed is:

1. A solar cell, comprising:
a silicon substrate having a front surface and a back surface opposite to the front surface;
a first doped crystalline silicon region and a second doped crystalline silicon region that are arranged on the back surface of the silicon substrate, wherein a first surface of the first doped crystalline silicon region away from the silicon substrate and a second surface of the second doped crystalline silicon region away from the silicon substrate are polished surfaces; and
an isolation groove, configured to isolate the first doped crystalline silicon region and the second doped crystalline silicon region, wherein a first textured structure with pyramidal structures is arranged at a bottom of the isolation groove, a distribution density of apexes of the pyramidal structures ranging from 25/100 μm² to 80/100 μm²,
wherein the back surface of the silicon substrate comprises an overlapping region where the first doped crystalline silicon region and the second doped crystalline silicon region overlaps, wherein the overlapping region comprises a polished surface.

2. The solar cell according to claim 1, wherein along a thickness direction of the solar cell, a distance between the first surface of the first doped crystalline silicon region and the bottom of the isolation groove ranges from 3 μm to 6 μm.

3. The solar cell according to claim 1, wherein along a thickness direction of the solar cell, a distance between the second surface of the second doped crystalline silicon region and the bottom of the isolation groove ranges from 1 μm to 5 μm.

4. The solar cell according to claim 1, wherein the solar cell comprises a plurality of isolation grooves, wherein along a distribution direction of the plurality of isolation grooves, a width of an isolation groove of the plurality of isolation grooves ranges from 20 μm to 150 μm.

5. The solar cell according to claim 1, wherein the isolation groove extends into the silicon substrate by a depth ranging from 2.5 μm to 5.8 μm.

6. The solar cell according to claim 1, wherein a thickness of the first doped crystalline silicon region ranges from 100 nm to 500 nm, and a thickness of the second doped crystalline silicon region ranges from 100 nm to 500 nm.

7. The solar cell according to claim 1, wherein a cross-sectional shape of the isolation groove is a rectangle or a trapezoid.

8. The solar cell according to claim 1, further comprising a tunneling oxide layer, wherein the tunneling oxide layer is located between the silicon substrate and the first doped crystalline silicon region, and is further located between the silicon substrate and the second doped crystalline silicon region, wherein a thickness of the tunneling oxide layer ranges from 0.5 nm to 3 nm.

9. The solar cell according to claim 1, wherein the front surface of the silicon substrate comprises a second textured structure with pyramidal structures.

10. The solar cell according to claim 9, wherein an apex angle of the pyramidal structures of the first textured structure is greater than an apex angle of the pyramidal structures of the second textured structure.

11. The solar cell according to claim 10, wherein the apex angle of the pyramidal structures of the first textured structure is greater than or equal to 79°, and the apex angle of the pyramidal structures of the second textured structure is less than 79°.

12. The solar cell according to claim 10, further comprising:
a first passivation anti-reflection layer on the front surface of the silicon substrate, wherein the first passivation anti-reflection layer comprises a first portion located on the second textured structure; and
a second passivation anti-reflection layer on the back surface of the silicon substrate, wherein the second passivation anti-reflection layer comprises a second portion located on the first textured structure,
wherein a thickness of the first portion is less than a thickness of the second portion.

13. The solar cell according to claim 10, wherein the solar cell comprises a second passivation anti-reflection layer on the back surface of the silicon substrate, wherein the second passivation anti-reflection layer comprises:
a second portion located on the first textured structure; and
a third portion located on the polished surface of the overlapping region, wherein a thickness of the second portion is less than a thickness of the third portion.

14. The solar cell according to claim 10, further comprising:
a first passivation anti-reflection layer on the front surface of the silicon substrate, wherein the first passivation anti-reflection layer comprises a first portion located on the second textured structure; and
a second passivation anti-reflection layer on the back surface of the silicon substrate, wherein the second passivation anti-reflection layer comprises a second portion located on the first textured structure and a third portion located on the polished surface of the overlapping region,
wherein a thickness of the first portion is smaller than a thickness of the second portion, and the thickness of the second portion is smaller than a thickness of the third portion.

15. The solar cell according to claim 1, wherein the solar cell is a back contact solar cell.

16. A photovoltaic module, comprising a solar cell, wherein the solar cell comprises:
a silicon substrate having a front surface and a back surface opposite to the front surface;
a first doped crystalline silicon region and a second doped crystalline silicon region that are arranged on the back surface of the silicon substrate, wherein a first surface of the first doped crystalline silicon region away from the silicon substrate and a second surface of the second doped crystalline silicon region away from the silicon substrate are polished surfaces; and
an isolation groove, configured to isolate the first doped crystalline silicon region and the second doped crystalline silicon region, wherein a first textured structure with pyramidal structures is arranged at a bottom of the isolation groove, a distribution density of apexes of the pyramidal structures ranging from 25/100 μm² to 80/100 μm²,
wherein the back surface of the silicon substrate comprises an overlapping region where the first doped crystalline silicon region and the second doped crystalline silicon region overlaps, wherein the overlapping region comprises a polished surface.
